(19) United States
(12) Patent Application Publication
(10) Pub. No.: US 2025/0391696 A1
(43) Pub. Date: Dec. 25, 2025

(54) ELECTROSTATIC CHUCK

(71) Applicant: TOTO LTD., Fukuoka (JP)

(72) Inventors: Masafumi IKEGUCHI, Fukuoka (JP); Tatsuya MORI, Fukuoka (JP); Tomoki UMETSU, Fukuoka (JP)

(73) Assignee: TOTO LTD., Fukuoka (JP)

(21) Appl. No.: 19/236,488

(22) Filed: Jun. 12, 2025

(30) Foreign Application Priority Data
Jun. 19, 2024 (JP) 2024-098478

(51) Int. Cl. H01L 21/683; H05B 3/06

(52) U.S. Cl. CPC H01L 21/6833; H05B 3/06

(57) ABSTRACT

An electrostatic chuck 10 includes a dielectric substrate 100 and a heater for heating the dielectric substrate 100. The heater includes a built-in heater 300 provided inside the dielectric substrate 100, and an external heater unit 400 provided outside the dielectric substrate 100.

### CROSS-REFERENCE TO RELATED APPLICATION

This application is based upon and claims the benefit of priority from Japanese Patent Application No. 2024-098478 filed on Jun. 19, 2024, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to adsorb and hold a wafer such as a silicon wafer to be processed. The electrostatic chuck includes a dielectric substrate on which an adsorption electrode is provided. When a voltage is applied to the adsorption electrode, an electrostatic force is generated, and the wafer placed on the dielectric substrate is adsorbed and held.

During a process on the wafer, an in-plane temperature distribution of the wafer is required to be as uniform as possible. To enable the in-plane temperature distribution of the wafer to be regulated with high accuracy, an electrostatic chuck including a heater for heating the dielectric substrate has been developed in recent years, which has already been put to practical use. For example, Japanese Patent Laid-Open No. 2022-55292 discloses an electrostatic chuck including both of a low-power sub-heater and a high-power main heater. With such a configuration, a temperature of the wafer can be raised in a short time by the main heater, or the in-plane temperature distribution of the wafer can be made uniform by the sub-heater, for example.

### SUMMARY

In the electrostatic chuck disclosed in Japanese Patent Laid-Open No. 2022-55292 described above, the whole of the main heater and the sub-heater is provided outside the dielectric substrate in a unitized state. By providing the whole heater on the outside of the dielectric substrate instead of the inside thereof, the dielectric substrate can be made thinner. However, as compared with a configuration in which the whole heater is provided inside the dielectric substrate, it may become difficult to precisely regulate the in-plane temperature distribution of the wafer.

The present invention has been made in view of such a problem, and aims at providing an electrostatic chuck that can suppress a thickness of the dielectric substrate while enabling an in-plane temperature distribution of a wafer to be precisely regulated by a heater.

To solve the above-described problem, the electrostatic chuck according to the present invention includes a dielectric substrate including a placement surface on which an object to be adsorbed is placed, and a heater configured to heat the dielectric substrate. The heater includes a first heater provided inside the dielectric substrate, and a second heater provided outside the dielectric substrate.

In the electrostatic chuck having such a configuration, the first heater is provided inside the dielectric substrate, so that the in-plane temperature distribution of the wafer can be regulated more precisely. Instead of providing the whole heater inside the dielectric substrate, the second heater is provided outside the dielectric substrate, so that the dielectric substrate is prevented from being too thick due to the built-in heater.

According to the present invention, it is possible to provide an electrostatic chuck that can suppress a thickness of a dielectric substrate while enabling an in-plane temperature distribution of a wafer to be precisely regulated by a heater.

### BRIEF DESCRIPTION OF THE DRAWINGS

FIG. 1 is a cross sectional view schematically illustrating a configuration of an electrostatic chuck according to a first embodiment;

FIG. 2 is a diagram illustrating an example of a manner of dividing a built-in heater;

FIG. 3 is a diagram illustrating an example of a first heat generation part routed in one region;

FIG. 4 is a diagram for explaining a role of a first bypass part and the like;

FIG. 5 is an exploded view schematically illustrating a configuration of an external heater unit;

FIG. 6 is a diagram illustrating an example of a manner of dividing a heat generation layer in the external heater unit;

FIG. 7 is a diagram illustrating an example of a second heat generation part routed in one region;

FIG. 8 is a diagram for explaining a role of a second bypass part and the like; and

FIG. 9 is a cross sectional view schematically illustrating a configuration of an electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

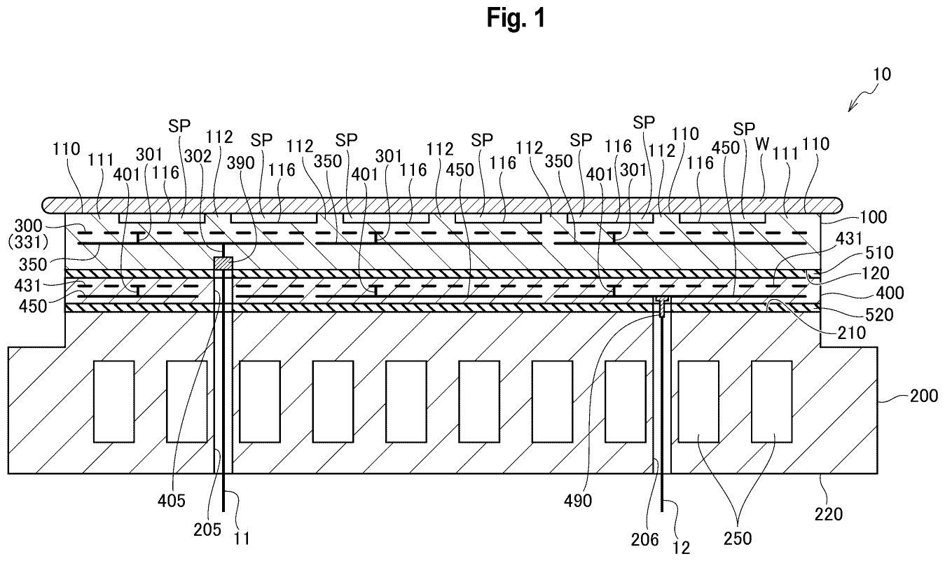

FIG. 1 is a cross sectional view schematically illustrating a configuration of the electrostatic chuck 10 in a state in which the wafer W is adsorbed and held. The electrostatic chuck 10 includes a dielectric substrate 100, a base plate 200, a built-in heater 300, and an external heater unit 400.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the external heater unit 400 via a joining layer 510. A perspective in a case where the electrostatic chuck 10 is viewed from the surface 110 side along a direction perpendicular to the surface 110 will also be hereinafter expressed as “top view”.

An adsorption electrode which is not illustrated in the drawing is embedded inside the dielectric substrate 100. The adsorption electrode is a thin planar layer made of a metallic material such as, for example, tungsten, and is arranged so as to be parallel to the surface 110. As a material of the adsorption electrode, molybdenum, platinum, palladium, and the like may be used in addition to tungsten. When a voltage is applied to the adsorption electrode from an outside, an electrostatic force is generated between the surface 110 and the wafer W, and according to this, the wafer W is adsorbed and held.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is interposed between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The base plate 200 is a substantially disk-shaped member that supports the dielectric substrate 100 and the external heater unit 400. The base plate 200 is made of, for example, a metallic material such as aluminum. A surface 210 on the upper side in FIG. 1 in the base plate 200 serves as a “surface to be joined” which is joined to the external heater unit 400 via a joining layer 520.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

An insulating film may be formed on a surface of the base plate 200. As the insulating film, for example, an alumina film formed by thermal spraying can be used. When the surface of the base plate 200 is covered by the insulating film, it is possible to increase a withstand voltage of the base plate 200.

The built-in heater 300 generates heat by receiving power supplied from the outside, and heats the dielectric substrate 100. The built-in heater 300 is provided inside the dielectric substrate 100. The built-in heater 300 includes a first heat generation part 331, a first bypass part 350, and a first power supply terminal 390.

The first heat generation part 331 is a conductor that is linearly routed, and is a portion that generates heat by receiving power supplied from the outside. The first heat generation part 331 is routed along a surface parallel to the surface 110 at a height position closer to the surface 120 side (the lower side in FIG. 1) than the adsorption electrode which is not illustrated in the drawing.

The built-in heater 300 is divided into a plurality of regions that are not overlapped with each other in top view, and the one first heat generation part 331 is routed in each of the regions. That is, the built-in heater 300 includes a plurality of first heat generation parts 331 corresponding to the number of the above-described regions. By individually regulating a heating value at each of the first heat generation parts 331, an in-plane temperature distribution of the wafer W during the process can be made approximately uniform.

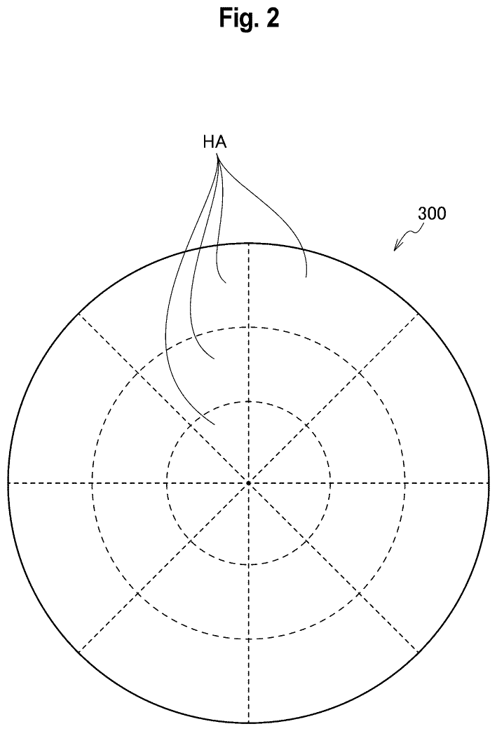

FIG. 2 illustrates an example of a manner of dividing the regions in the built-in heater 300 in top view. In this example, the built-in heater 300 is divided into twenty-four regions HA in total. The linear first heat generation part 331 is individually routed in each of the regions HA. That is, the twenty-four first heat generation parts 331 in total are provided in the present embodiment.

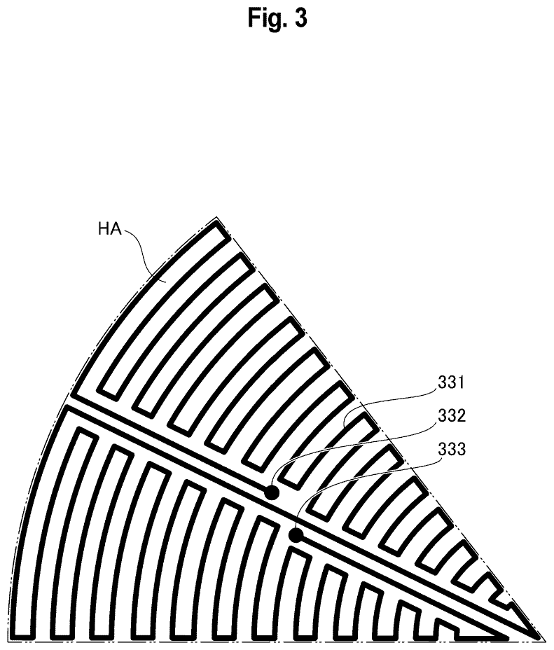

FIG. 3 illustrates an example of the first heat generation part 331 routed in the one region HA. In each of the regions HA, the one linear first heat generation part 331 is routed along a path uniformly passing through substantially the entire range thereof.

At both ends of the first heat generation part 331, circular pad parts 332 and 333 are respectively formed. The first heat generation part 331 and the pad parts 332 and 333 are formed by screen printing a metallic material such as tungsten, for example. A shape of the first heat generation part 331 illustrated in FIG. 3 is schematic, and is different from a real shape. The same applies to positions of the pad parts 332 and 333.

Power is supplied to the first heat generation part 331 via the first power supply terminal 390 and the first bypass part 350. As illustrated in FIG. 1, the first power supply terminal 390 is a terminal made of metal embedded in the surface 120 of the dielectric substrate 100. The first power supply terminal 390 includes a plurality of first power supply terminals 390 that are provided corresponding to the respective first heat generation parts 331, but only one of them is illustrated in FIG. 1. The first power supply terminal 390 is electrically connected to the first bypass part 350 that is present immediately above the first power supply terminal 390 via a via 302 provided inside the dielectric substrate 100. The via 302 is an electric circuit that is provided by filling metal such as tungsten, for example, into an inner part of a hole extending perpendicularly to the surface 110.

The first bypass part 350 is a thin planar layer made of a metallic material such as tungsten. The first bypass part 350 is provided inside the dielectric substrate 100 at a height position closer to the surface 120 side than the first heat generation part 331. The first bypass part 350 is electrically connected to the first heat generation part 331 via a via 301 provided inside the dielectric substrate 100. The via 301 is an electric circuit that is provided by filling metal such as tungsten, for example, into an inner part of a hole extending perpendicularly to the surface 110. In this way, the first heat generation part 331 is electrically connected to the first power supply terminal 390 via the via 301, the first bypass part 350, and the via 302.

One end of a bus bar 11 is connected to the first power supply terminal 390. Power supply to the first power supply terminal 390 from the outside is performed via the bus bar 11. The bus bar 11 is inserted through a through hole 405 formed in the external heater unit 400 and a through hole 205 formed in the base plate 200.

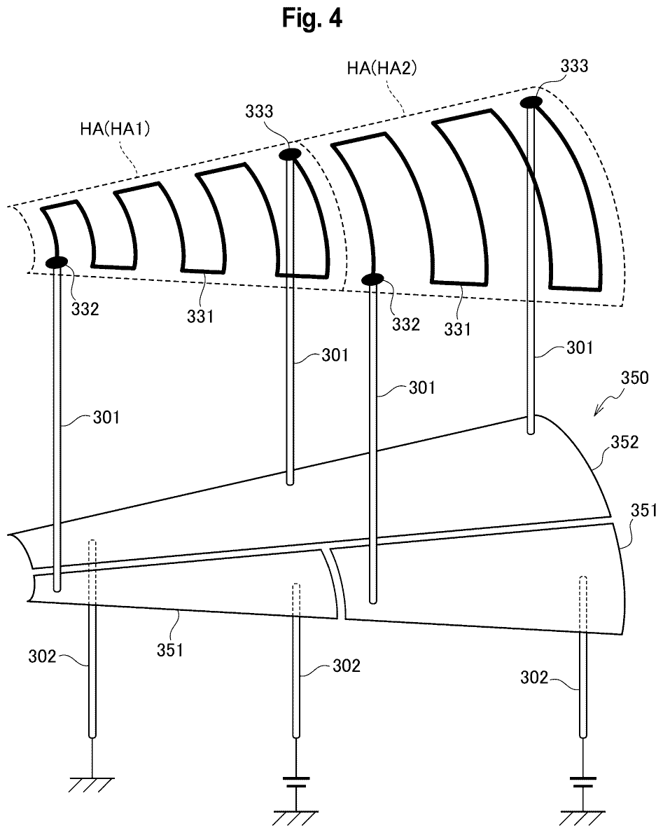

FIG. 4 illustrates a schematic perspective view of configurations of the two regions HA, the two first heat generation parts 331 routed therein, the first bypass part 350 connected to the first heat generation parts 331, and the like. One of the two regions HA illustrated in FIG. 4 will also be hereinafter referred to as a “region HA1”. The other one of the regions HA will also be hereinafter referred to as a “region HA2”. Shapes of the first heat generation part 331 and the like illustrated in FIG. 4 are schematic, and are different from real shapes.

The first bypass part 350 includes a plurality of first bypass parts 350 that are provided corresponding to the respective first power supply terminals 390. FIG. 4 illustrates only three of the plurality of first bypass parts 350. Each of the plurality of first bypass parts 350 denoted by reference sign “351” in FIG. 4 is arranged at a position overlapped with only one of the regions HA in top view. That is, it is individually arranged at a position immediately below each of the regions HA. A portion of the first bypass part 350 that is arranged as described above will also be hereinafter referred to as a “first bypass part 351”.

One of the plurality of first bypass parts 350 denoted by reference sign “352” in FIG. 4 is arranged at a position overlapped with both of the region HA1 and the region HA2 in top view. A portion of the first bypass part 350 that is arranged as described above will also be hereinafter referred to as a “first bypass part 352”.

In the first heat generation part 331 arranged in the region HA1, the pad part 332 at one end of the first heat generation part 331 is electrically connected to the first bypass part 351 that is present immediately below the pad part 332 via the via 301. The pad part 333 at the other end of the first heat generation part 331 is electrically connected to the first bypass part 352 via the via 301.

Similarly to the above, also in the first heat generation part 331 arranged in the region HA2, the pad part 332 at one end of the first heat generation part 331 is electrically connected to the first bypass part 351 that is present immediately below the pad part 332 via the via 301. The pad part 333 at the other end of the first heat generation part 331 is electrically connected to the first bypass part 352 via the via 301.

Vias 302 are connected to the respective first bypass parts 351 from the lower side in FIG. 4. A voltage is individually applied to each of the vias 302 from an external DC power supply via the first power supply terminal 390 and the bus bar 11 that are not illustrated in FIG. 4. The via 302 is also connected to the first bypass part 352 from the lower side in FIG. 4. The via 302 is grounded via the first power supply terminal 390 and the bus bar 11 that are not illustrated in FIG. 4. The DC power supply and a grounding portion illustrated in FIG. 4 are part of a circuit for temperature control connected to the electrostatic chuck 10 from the outside.

As described above, in each of the first heat generation parts 331 provided for each of the regions HA, the one pad part 332 is connected to the individual DC power supply via the first bypass part 351, and the other pad part 333 is grounded via the common first bypass part 352. The other first heat generation parts 331 not illustrated in FIG. 4 are also connected to the DC power supply and the like with the same configuration. With such a configuration, it is possible to individually supply power to each of the plurality of first heat generation parts 331, and regulate a heating value at each part.

It is also possible to supply power directly from the first power supply terminal 390 to the first heat generation part 331 without using the first bypass part 350. However, with the configuration of supplying power via the first bypass part 350 as in the present embodiment, a degree of freedom in arrangement of the first power supply terminal 390 can be enhanced, or the first power supply terminals 390 to be grounded can be integrated into one terminal.

As described above, the whole built-in heater 300 including the first heat generation part 331 is provided inside the dielectric substrate 100. The built-in heater 300 corresponds to a “first heater” in the present embodiment. It is possible to adopt an aspect in which portions other than the first heat generation parts 331 in the built-in heater 300 (for example, the first bypass parts 350) are provided outside the dielectric substrate 100.

Similarly to the above-described built-in heater 300, the external heater unit 400 generates heat by receiving power supplied from the outside, and heats the dielectric substrate 100. However, the external heater unit 400 is unitized as a whole, and provided outside the dielectric substrate 100. A shape of the external heater unit 400 is a substantially disc shape.

As illustrated in FIG. 1, the external heater unit 400 is sandwiched between the dielectric substrate 100 and the base plate 200, and joined to each of them. The external heater unit 400 is joined to the dielectric substrate 100 via the joining layer 510, and the external heater unit 400 is joined to the base plate 200 via the joining layer 520. Each of the joining layers 510 and 520 is a layer formed by curing a silicone adhesive, for example. In an inner part of each of the joining layers 510 and 520, a plurality of particulate fillers for enhancing thermal conductivity are arranged. As the filler, for example, particles containing alumina as a principal component can be used.

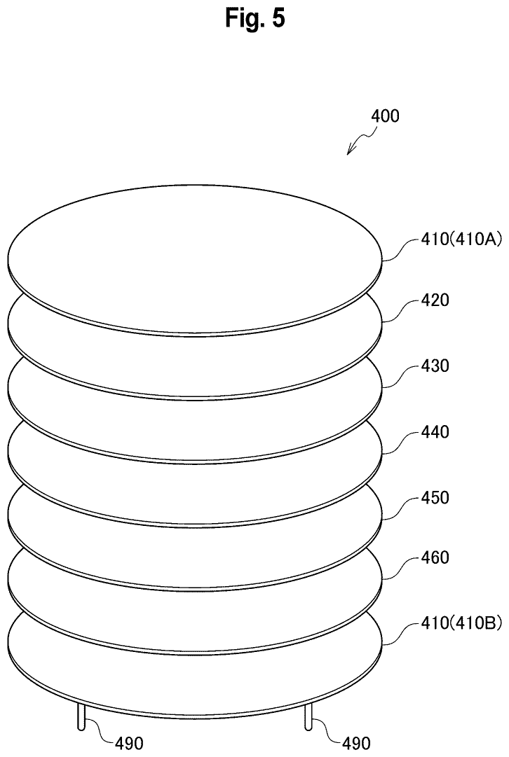

A specific configuration of the external heater unit 400 will be described. FIG. 5 illustrates a configuration of the external heater unit 400 as a schematic exploded view. As illustrated in FIG. 5, the external heater unit 400 includes a support plate 410 (410A), an insulating layer 420, a heat generation layer 430, an insulating layer 440, a second bypass part 450, an insulating layer 460, a support plate 410 (410B), and a second power supply terminal 490.

The support plate 410 is a substantially disc-shaped member, and provided at each of end parts on upper and lower sides in FIG. 5 of the external heater unit 400. The support plate 410 provided at the end part on the upper side in FIG. 5 will also be hereinafter referred to as a “support plate 410A”. The support plate 410 provided at the end part on the lower side in FIG. 5 will also be hereinafter referred to as a “support plate 410B”. The support plate 410A is a portion to be joined to the dielectric substrate 100 via the joining layer 510, and the support plate 410B is a portion to be joined to the base plate 200 via the joining layer 520.

A pair of the support plates 410A and 410B are members for reinforcing the whole external heater unit 400 by sandwiching the whole of the heat generation layer 430, the second bypass part 450, and the like therebetween. In the present embodiment, both of the support plates 410A and 410B are made of metal, but may be made of another member (for example, an insulating member). In each member such as the support plate 410 constituting the external heater unit 400, a plurality of through holes such as a gas hole or a lift pin hole, the through hole 405 illustrated in FIG. 1, and the like are formed, but these through holes are not illustrated in FIG. 5.

The insulating layer 420 is a layer provided between the support plate 410A and the heat generation layer 430 to electrically insulate therebetween. The insulating layer 420 also has a role of physically joining the support plate 410A with the heat generation layer 430. The insulating layer 420 is a polyimide film in the present embodiment, but may contain components other than polyimide, and may be made of a material different from polyimide. In a case in which the support plate 410A is made of an insulating material, the insulating layer 420 can be eliminated.

The heat generation layer 430 is a portion that generates heat by receiving power supplied from the outside. In FIG. 5, the heat generation layer 430 is schematically illustrated as a single disc, but the heat generation layer 430 is actually divided into a plurality of regions that are not overlapped with each other in top view, and each of the regions can be caused to individually generate heat. A specific configuration of the heat generation layer 430 will be described later.

The insulating layer 440 is a layer provided between the heat generation layer 430 and the second bypass part 450 to electrically insulate therebetween. The insulating layer 440 also has a role of physically joining the heat generation layer 430 with the second bypass part 450. The insulating layer 440 is a polyimide film in the present embodiment, but may contain components other than polyimide, and may be made of a material different from polyimide.

The second bypass part 450 is a layer for electrically connecting between the second power supply terminal 490 and the heat generation layer 430 (specifically, between the second power supply terminal 490 and the second heat generation part 431). In FIG. 2, the second bypass part 450 is schematically illustrated as a single disc, but the second bypass part 450 is actually divided into a plurality of parts. By providing the second bypass part 450 in a middle of an electric circuit connected to the heat generation layer 430, it is possible to regulate a position of the second power supply terminal 490 and the like. Each of the divided parts of the second bypass part 450 is partially electrically connected to the heat generation layer 430.

The insulating layer 460 is a layer provided between the second bypass part 450 and the support plate 410B to electrically insulate therebetween. The insulating layer 460 also has a role of physically joining the second bypass part 450 with the support plate 410B. The insulating layer 460 is a polyimide film in the present embodiment, but may contain components other than polyimide, and may be made of a material different from polyimide. In a case in which the support plate 410B is made of an insulating material, the insulating layer 460 can be eliminated.

At the time of manufacturing the external heater unit 400, the respective layers illustrated in FIG. 5 are pressurized and heated as a whole in a laminated state. Due to this, the whole layers are joined and integrated with each other via the insulating layer 420 that is a polyimide film and the like.

The second power supply terminal 490 is a portion that receives power required for causing the heat generation layer 430 to generate heat from the outside. In the present embodiment, the second power supply terminal 490 is formed as a long and narrow stick-shaped plug. One end of the second power supply terminal 490 is connected to the second bypass part 450 through openings which are respectively formed in the insulating layer 460 and the support plate 410B and not illustrated in the drawing.

The second power supply terminal 490 includes a plurality of second power supply terminals 490 that are provided corresponding to the respective second heat generation parts 431, but only two of them is illustrated in FIG. 5. As illustrated in FIG. 1, a through hole 206 is formed at each position corresponding to the second power supply terminal 490 in the base plate 200, and the second power supply terminal 490 is inserted through the through hole 206.

One end of a bus bar 12 is connected to the second power supply terminal 490. Power supply to the second power supply terminal 490 from the outside is performed via the bus bar 12. The bus bar 12 is also inserted through the through hole 206.

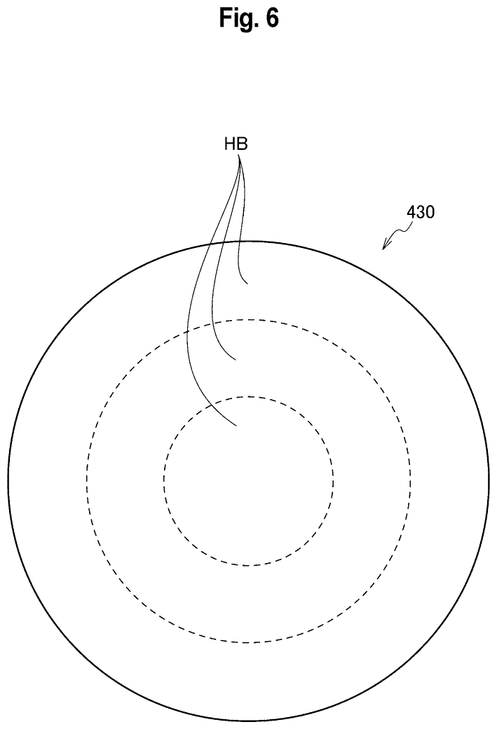

A configuration of the heat generation layer 430 included in the external heater unit 400 will be described. As described above, the heat generation layer 430 is divided into the plurality of regions, and heat can be individually generated in each of the regions. FIG. 6 illustrates an example of a manner of dividing the heat generation layer 430 in top view. In this example, the heat generation layer 430 is divided into three regions HB in total.

The heat generation layer 430 is configured as the linear second heat generation part 431, and individually routed in each of the regions HB. That is, three second heat generation parts 431 in total are provided in the present embodiment.

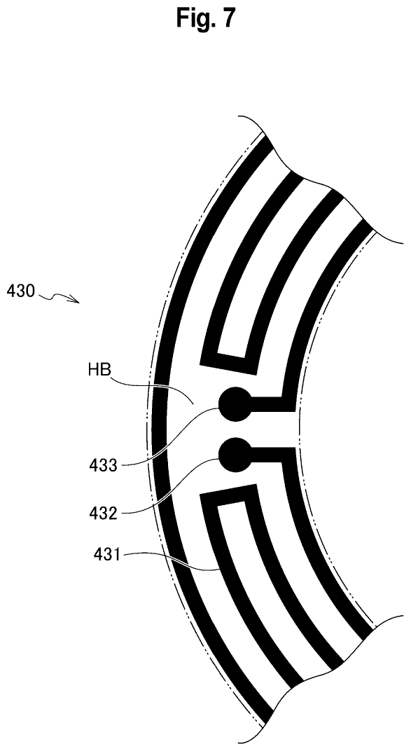

FIG. 7 illustrates an example of the second heat generation part 431 routed in the one region HB in top view. In each of the regions HB, the one linear second heat generation part 431 is routed along a path uniformly passing through substantially the entire range thereof. The second heat generation part 431 is a portion that generates heat by receiving power supplied from the outside.

At both ends of the second heat generation part 431, circular pad parts 432 and 433 are respectively formed. The second heat generation part 431 and the pad parts 432 and 433 are formed by performing etching on thin metal foil, for example. A shape of the second heat generation part 431 illustrated in FIG. 6 is schematic, and is different from a real shape. The same applies to positions of the pad parts 432 and 433.

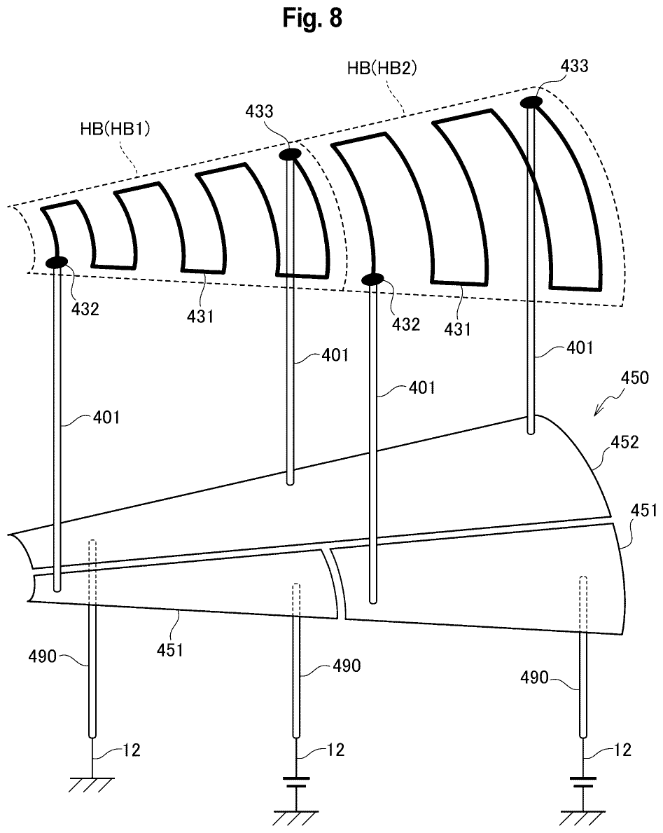

FIG. 8 illustrates a schematic perspective view of configurations of the two regions HB, the two second heat generation parts 431 routed therein, the second bypass part 450 connected to the second heat generation parts 431, and the like. For convenience of explanation, in FIG. 8, a shape of each of the regions HB is schematically illustrated as a shape different from a real shape. The same applies to a shape of the second heat generation part 431, a shape of the second bypass part 450, and the like.

One of the two regions HB illustrated in FIG. 8 will also be hereinafter referred to as a “region HB1”. The other one of the regions HB will also be hereinafter referred to as a “region HB2”.

As described above, the second bypass part 450 is divided into the plurality of parts. FIG. 8 illustrates only three of the plurality of divided second bypass parts 450. Each of the three divided second bypass parts 450 denoted by reference sign “451” in FIG. 8 is arranged at a position overlapped with only one of the regions HB in top view. That is, it is individually arranged at a position immediately below each of the regions HB. A portion of the second bypass part 450 that is arranged as described above will also be hereinafter referred to as a “second bypass part 451”.

One of the divided second bypass parts 450 denoted by reference sign “452” in FIG. 8 is arranged at a position overlapped with both of the region HB1 and the region HB2 in top view. A portion of the second bypass part 450 that is arranged as described above will also be hereinafter referred to as a “second bypass part 452”.

In the second heat generation part 431 arranged in the region HB1, the pad part 432 at one end of the second heat generation part 431 is electrically connected to the second bypass part 451 that is present immediately below the pad part 432. The pad part 433 at the other end of the second heat generation part 431 is electrically connected to the second bypass part 452.

Similarly to the above, in the second heat generation part 431 arranged in the region HB2, the pad part 432 at one end of the second heat generation part 431 is electrically connected to the second bypass part 451 that is present immediately below the pad part 432. The pad part 433 at the other end of the second heat generation part 431 is electrically connected to the second bypass part 452.

The electrical connection between the respective parts as described above are implemented by welding upper and lower layers to each other, for example. For ease of understanding of the configuration, in FIG. 8, each welding part is schematically illustrated as a stick-shaped member extending in a straight line (a portion denoted by reference sign “401”). At a portion overlapped with each welding part in top view, an opening is formed in the insulating layer 440 between the heat generation layer 430 and the second bypass part 450, and the heat generation layer 430 (specifically, the pad parts 432 and 433) is directly connected to the second bypass part 450 via the opening.

The heat generation layer 430 and the second bypass part 450 may be electrically connected by welding as in the present embodiment, but may be electrically connected by using another method. For example, they may be electrically connected via a conductive member extending in an upper and lower direction. In any configuration, the electric circuit denoted by reference sign “401” in FIG. 8 is formed between the heat generation layer 430 and the second bypass part 450. This electric circuit will also be hereinafter referred to as an “electric circuit 401”.

One end of the second power supply terminal 490 is connected to each of second bypass parts 451 from the lower side in FIG. 8. A voltage is individually applied to each of the second power supply terminals 490 via the bus bar 12 from an external DC power supply. One end of the second power supply terminal 490 is also connected to the second bypass part 452 from the lower side in FIG. 8. The second power supply terminal 490 is grounded via the bus bar 12. The DC power supply and a grounding portion illustrated in FIG. 8 are part of a circuit for temperature control connected to the electrostatic chuck 10 from the outside.

As described above, in each of the second heat generation parts 431 provided for each of the regions HB, the one pad part 432 is connected to the individual DC power supply via the second bypass part 451, and the other pad part 433 is grounded via the common second bypass part 452. The other second heat generation parts 431 not illustrated in FIG. 8 are also connected to the DC power supply and the like with the same configuration. With such a configuration, it is possible to individually supply power to each of the plurality of second heat generation parts 431, and regulate a heating value at each part.

It is also possible to supply power directly from the second power supply terminal 490 to the second heat generation part 431 without using the second bypass part 450. However, with the configuration of supplying power via the second bypass part 450 as in the present embodiment, a degree of freedom in arrangement of the second power supply terminal 490 can be enhanced, or the second power supply terminals 490 to be grounded can be integrated into one terminal.

As described above, the whole external heater unit 400 including the second heat generation part 431 is provided outside the dielectric substrate 100. The external heater unit 400 corresponds to a “second heater” in the present embodiment.

A heating value per unit area of the external heater unit 400 is larger than that of the built-in heater 300 described above. The external heater unit 400 is used for raising a temperature of the whole dielectric substrate 100 in a short time. The built-in heater 300 is used for regulating a temperature of each part of the dielectric substrate 100, and making the in-plane temperature distribution of the wafer W approximately uniform. That is, the external heater unit 400 is used as a main heater for raising a temperature, and the built-in heater 300 is used as a sub-heater for regulation. In this way, in the present embodiment, the two heaters having respective roles are individually provided.

In the electrostatic chuck 10, the subdivided first heat generation parts 331 with a small heating value per unit area are provided inside the dielectric substrate 100. Due to this, the in-plane temperature distribution of the wafer W can be regulated more precisely.

Similarly to the first heat generation parts 331 for precise regulation, it can be considered that the second heat generation parts 431 for raising a temperature may be provided inside the dielectric substrate 100. However, in a case of providing the whole heater inside the dielectric substrate 100, the dielectric substrate 100 becomes too thick. When the dielectric substrate 100 becomes too thick, an impedance of a circuit including the dielectric substrate 100 is increased accordingly, so that a problem may be caused such that an electric discharge is easily caused during a process on the wafer W.

Thus, in the present embodiment, as described above, instead of providing the whole heater inside the dielectric substrate 100, a part of the heater is provided outside the dielectric substrate 100 as the external heater unit 400. With such a configuration, it is possible to suppress the thickness of the dielectric substrate 100 while enabling the in-plane temperature distribution of the wafer W to be precisely regulated. As compared with the case of providing the whole heater inside the dielectric substrate 100, an advantage can be obtained such that manufacture of the dielectric substrate 100 is facilitated.

Variation at the time of manufacture of the second heat generation parts 431 for raising a temperature is larger than that of the first heat generation part 331 for regulation, and it is difficult to stably obtain constant quality in many cases. Due to this, if the second heat generation part 431 is built in the dielectric substrate 100, a yield of the dielectric substrate 100 may be lowered. As in the present embodiment, in the case of providing the second heat generation part 431 outside the dielectric substrate 100, an advantage can be obtained such that the yield of the dielectric substrate 100 is improved.

In the present embodiment, similarly to the first heat generation part 331, the first bypass part 350 is also provided inside the dielectric substrate 100. The first bypass part 350 is provided at a position between the first heat generation part 331 and the second heat generation part 431 in a direction perpendicular to the surface 110 as the placement surface, that is, at a height position closer to the surface 110 side than the second heat generation part 431. With such a configuration, in arranging the first bypass part 350, there is no need to take into account interference with the electric circuit 401 connected to the second heat generation part 431, so that the first bypass part 350 can be arranged with a high degree of freedom.

The electrostatic chuck 10 according to the present embodiment includes the built-in heater 300 and the external heater unit 400 as heaters for heating the dielectric substrate 100. As a heater for heating the dielectric substrate 100, the electrostatic chuck 10 may further include a heater different therefrom.

A second embodiment will be described below. Hereinafter, an aspect different from the first embodiment will be mainly described, and descriptions on an aspect common to the first embodiment are not repeated as appropriate.

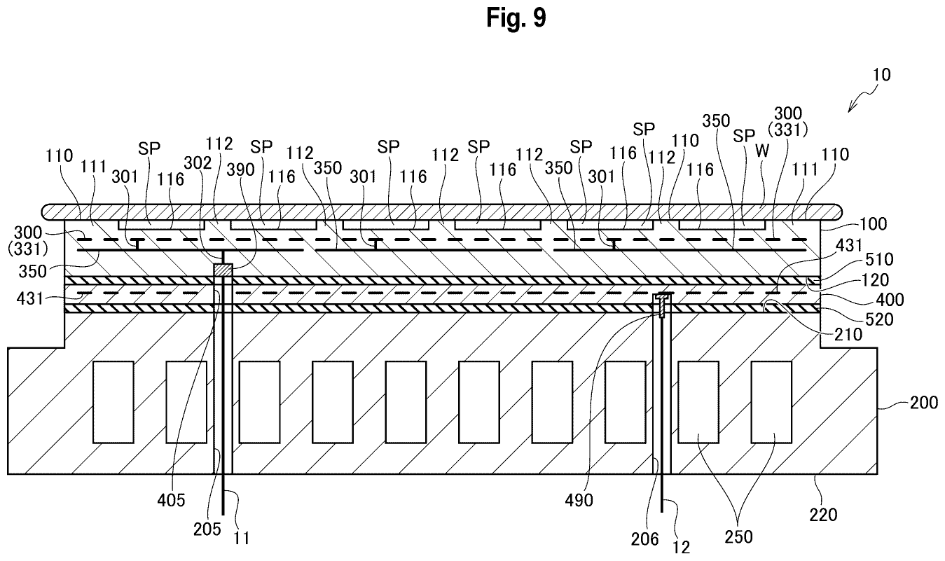

FIG. 9 schematically illustrates a configuration of the electrostatic chuck 10 according to the present embodiment from the same viewpoint as in FIG. 1. In the present embodiment, the second bypass part 450 is not provided in the external heater unit 400, and respective ends of the second power supply terminals 490 are directly connected to the pad parts 432 and 433 at the end parts of the second heat generation part 431. With such a configuration, manufacturing cost of the external heater unit 400 can be reduced.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be adsorbed is placed; and
a heater configured to heat the dielectric substrate, wherein
the heater includes
a first heater provided inside the dielectric substrate, and
a second heater provided outside the dielectric substrate.

2. The electrostatic chuck according to claim 1, wherein the first heater includes:
a plurality of first heat generation parts that are conductors linearly routed inside the dielectric substrate;
a plurality of first power supply terminals that are provided corresponding to the plurality of first heat generation parts, respectively; and
a plurality of first bypass parts configured to electrically connect between the plurality of first heat generation parts and the plurality of first power supply terminals.

3. The electrostatic chuck according to claim 2, wherein the plurality of first bypass parts are provided inside the dielectric substrate.

4. The electrostatic chuck according to claim 1, wherein the second heater includes:
a plurality of second heat generation parts that are conductors linearly routed outside the dielectric substrate; and
a plurality of second power supply terminals that are provided corresponding to the plurality of second heat generation parts, respectively.

5. The electrostatic chuck according to claim 4, further comprising:
a plurality of second bypass parts configured to electrically connect between the plurality of second heat generation parts and the plurality of second power supply terminals.

6. The electrostatic chuck according to claim 5, wherein the plurality of second bypass parts are provided outside the dielectric substrate.

7. The electrostatic chuck according to claim 4, wherein each of the plurality of second power supply terminals is directly connected to a respective second heat generation part of the plurality of second heat generation parts.

8. The electrostatic chuck according to claim 1, wherein a heating value of the second heater per unit area is larger than a heating value of the first heater per unit area.
